(19) United States
(12) Patent Application Publication
(10) Pub. No.: US 2012/0313233 A1
(43) Pub. Date: Dec. 13, 2012

(54) Semiconductor Package, Stacking Semiconductor Package, And Method Of Fabricating The Same

(76) Inventor: Kyung Teck Boo, Cheonan-city (KR)

(21) Appl. No.: 13/476,591

(22) Filed: May 21, 2012

(30) Foreign Application Priority Data
Jun. 8, 2011 (KR) 10-2011-0055275

(51) Int. Cl. H01L 23/495; H01L 21/60

(52) U.S. Cl. 257/676; 438/107; 257/E23.052; 257/E21.51

(57) ABSTRACT

A stackable semiconductor package, a stacked semiconductor package that uses the stackable semiconductor packages, and a method of fabricating the same. The semiconductor package includes a die paddle unit having a first surface and a second surface opposite to the first surface, a semiconductor die attached to the first surface of the die paddle unit, a plurality of leads each including a first external terminal unit, a second external terminal unit, and a connection lead unit that connects the first external terminal unit to the second external terminal unit, a bonding wire that connects the semiconductor die to the first external terminal unit, and a sealing member formed to expose the first external terminal unit and the second external terminal unit and to surround the semiconductor die and the bonding wire.

### CROSS-REFERENCE TO RELATED APPLICATIONS

This application claims the benefit of Korean Patent Application No. 10-2011-0055275, filed on Jun. 8, 2011, in the Korean Intellectual Property Office, the disclosure of which is incorporated herein in its entirety by reference.

### FIELD OF THE INVENTION

The present invention relates to a semiconductor package, a stacked semiconductor package, and a method of fabricating the same, and more particularly, to a stackable semiconductor package, a stacked semiconductor package using the stackable semiconductor package, and a method of fabricating the same.

### BACKGROUND OF THE INVENTION

Electronic products require processing of high capacity data while the size thereof is gradually reduced. Accordingly, semiconductor devices used in the electronic products require high integration. Also, as the functions of electronic products are combined, a need for a single package having a multiple function increases.

For this, studies have been conducted to stack semiconductor chips or semiconductor packages. However, when the semiconductor chips or semiconductor packages are stacked, electronic connection therebetween is needed. However, the electronic connection makes the fabrication process complicated and increases fabrication costs.

### SUMMARY OF THE INVENTION

The present invention provides a stackable semiconductor package, a stacked semiconductor package that uses the stackable semiconductor packages, and a method of fabricating the same.

According to an aspect of the present invention, there is provided a semiconductor package including: a die paddle unit having a first surface and a second surface opposite to the first surface; a semiconductor die attached to the first surface of the die paddle unit; a plurality of leads each including a first external terminal unit, a second external terminal unit, and a connection lead unit that connects the first external terminal unit to the second external terminal unit; a bonding wire that connects the semiconductor die to the first external terminal unit; and a sealing member formed to expose the first external terminal unit and the second external terminal unit and to surround the semiconductor die and the bonding wire.

The first external terminal unit and the die paddle unit may be disposed on the same imaginary plane and the sealing member may be formed to expose the second surface of the die paddle unit.

The first external terminal unit and the second external terminal unit of each of the leads may partly overlap in a direction perpendicular to the second surface.

A distance between the first external terminal unit and the second external terminal unit may have a value greater than the thickness of the semiconductor die.

According to an aspect of the present invention, there is provided a stacked semiconductor package including: a first semiconductor chip and a second semiconductor chip each including: a die paddle unit having a first surface and a second surface opposite to the first surface; a semiconductor die attached to the first surface of the die paddle unit; a plurality of leads each including a first external terminal unit, a second external terminal unit, and a connection lead unit that connects the first external terminal unit to the second external terminal unit; a bonding wire that connects the semiconductor die to the first external terminal unit; and a sealing member formed to expose the first external terminal unit and the second external terminal unit and to surround the semiconductor die and the bonding wire, wherein the first semiconductor chip is stacked on the second semiconductor chip, and further includes a bump terminal disposed between the second external terminal unit of the first semiconductor chip and the first external terminal unit of the second semiconductor chip to electrically connect the first semiconductor chip to the second semiconductor chip.

According to an aspect of the present invention, there is provided a method of fabricating a stacked semiconductor package, the method including: preparing a lead frame having a first surface and a second surface opposite to the first surface, a plurality of leads each including a first external terminal unit, a second external terminal unit, and a connection lead unit that connects the first external terminal unit to the second external terminal unit, and a die paddle unit; forming the lead frame to form a first bending unit and a second bending unit respectively between the first external terminal unit and the connection lead unit and between the second external terminal unit and the connection lead unit; attaching the semiconductor die onto the first surface of the die paddle unit; forming a bonding wire that connects the semiconductor die to the first surface of the first external terminal unit; and forming a sealing member that surrounds some portions of the leads to expose the second surface of the first external terminal unit and the first surface of the second external terminal unit, the semiconductor die, and the bonding wire.

The forming of the lead frame may include disposing the first external terminal unit and the die paddle unit on the same imaginary plane.

The forming of the lead frame may include partly overlapping the first external terminal unit and the second external terminal unit of each of the leads in a direction perpendicular to the first surface.

The forming of the lead frame may include forming a distance between the first and second external terminal units of each the leads to be greater than the thickness of the semiconductor die.

The method may further include: preparing an upper semiconductor chip having an external connection terminal; forming a conductive bump on the first surface of the second external terminal unit; and attaching the upper semiconductor chip so that the conductive bump contacts the external connection terminal.

### BRIEF DESCRIPTION OF THE DRAWINGS

The above and other features and advantages of the present invention will become more apparent by describing in detail exemplary embodiments thereof with reference to the attached drawings in which:

FIGS. 1 through 3 are plan views of both surfaces of a semiconductor package and a cross-sectional view of a semiconductor package according to an embodiment of the present invention;

FIG. 4 is a cross-sectional view of a stacked semiconductor package according to an embodiment of the present invention;

FIG. 5 is a cross-sectional view of a modified version of a stacked semiconductor package according to an embodiment of the present invention;

FIGS. 6 and 7 are respectively a plan view and a cross-sectional view showing a process of preparing a lead frame according to an embodiment of the present invention;

FIG. 8 is a cross-sectional view showing an operation of forming a lead frame, according to an embodiment of the present invention;

FIG. 9 is a cross-sectional view showing an operation of attaching a semiconductor die, according to an embodiment of the present invention;

FIG. 10 is a cross-sectional view showing an operation of forming a bonding wire, according to an embodiment of the present invention; and

FIG. 11 is a cross-sectional view showing an operation of forming a sealing member, according to an embodiment of the present invention.

### DETAILED DESCRIPTION OF THE INVENTION

The present invention will now be described more fully with reference to the accompanying drawings in which exemplary embodiments of the invention are shown. This invention may, however, may be embodied in many alternate forms and should not be construed as limited to only the example embodiments and accompanying drawings set forth herein. It will be understood that when an element is referred to as being connected to another element, it can be directly connected to the other element or a third element may be interposed therebetween. Also, in the drawings, the shapes or sizes of elements are exaggerated for convenience of explanation and clarity, and portions that are not related to the descriptions are omitted. Also, in the drawings, like reference numerals refer to like elements. The terminology used herein is for the purpose of describing particular embodiments only and is not intended to be limiting of example embodiments described in the claims.

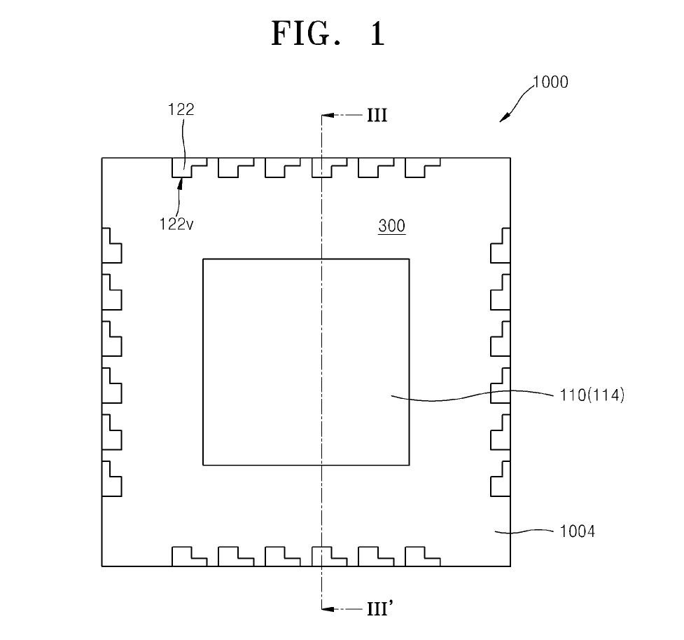

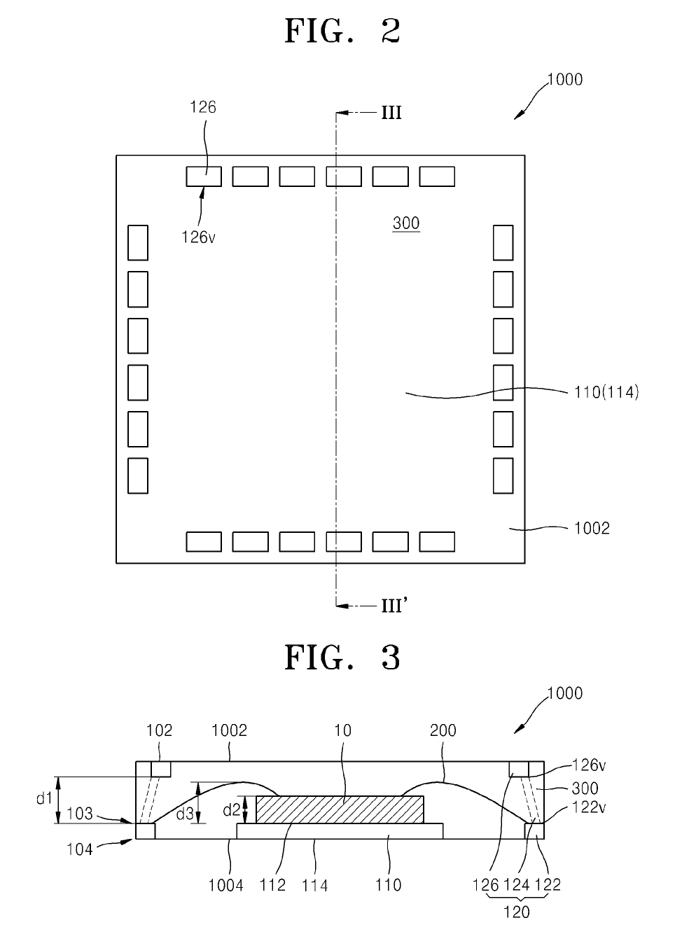

FIGS. 1 through 3 are plan views of both surfaces of a semiconductor package 1000 and a cross-sectional view of a semiconductor package 1000 according to an embodiment of the present invention. More specifically, FIG. 1 is a plan view of a bottom side of the semiconductor package 1000, FIG. 2 is a plan view of a top side of the semiconductor package 1000, and FIG. 3 is a cross-sectional view of the semiconductor package 1000 taken along a line III-III′ of FIG. 1 or 2.

Referring to FIGS. 1 through 3, the semiconductor package 1000 may have an upper surface 1002 and a lower surface 1004. A die paddle unit 110 (114) and a first external terminal unit 122 are exposed on the lower surface 1004 of the semiconductor package 1000, and a second external terminal unit 126 is exposed on the upper surface 1002 of the semiconductor package 1000. The remaining portion of the semiconductor package 1000 may be protected by sealing with a sealing member 300.

The semiconductor package 1000 may include the die paddle unit 110, a plurality of leads 120, a semiconductor die 10, a bonding wire 200, and the sealing member 300. The semiconductor package 1000 may be referred to as a semiconductor chip when the semiconductor package 1000 is used as an element that constitutes a stacking semiconductor package. Although it will be described below, the die paddle unit 110 and the leads 120 may be formed through a forming process from a single lead frame using a conductive metal. The die paddle unit 110 and the leads 120 may be formed through a forming process from a single copper lead frame on which a pre-plating is performed. The pre-plating may have a monolayer structure or a multiple layer structure using a metal selected from the group consisting of Ni, Au, and Ag.

The die paddle unit 110 may have a first surface 112 and a second surface 114, which is opposite to the first surface 112. The first surface 112 and the second surface 114 of the die paddle unit 110 may be a part of a first surface 102 and a second surface 104 of the lead frame, and the leads 120 may also have two surfaces which are parts of the first and second surfaces 102 and 104 of the lead frame.

The semiconductor die 10 may include highly integrated semiconductor memory devices, such as DRAMs, SRAMs, and flash memories, processors, such as central processor units (CPUs), digital signal processors (DSPs), and a combination of a CPU and a DSP, and individual semiconductor devices that constitute an application specific integrated circuit (ASIC), a micro electro mechanical system (MEMS) device, or an optoelectronic device. The semiconductor die 10 may be formed by separating a semiconductor wafer (not shown) on which the individual semiconductor devices are formed after back-grinding or back-lapping the semiconductor wafer.

The semiconductor die 10 may be attached to the first surface 112 of the die paddle unit 110. A surface of the semiconductor die 10 opposite to a surface that faces the die paddle unit 110 may be an active surface of the semiconductor die 10. In order to attach the semiconductor die 10 to the first surface 112 of the die paddle unit 110, a film on which an epoxy resin or an adhesive member is coated or a film having adhesiveness may be disposed between the semiconductor die 10 and the first surface 112 of the die paddle unit 110.

The leads 120 may each include the first external terminal unit 122, a connection lead unit 124, and the second external terminal unit 126. Before performing a forming process of the lead frame, the first external terminal unit 122, the connection lead unit 124, and the second external terminal unit 126 are on the same plane. However, through the forming process of the lead frame, a first bending unit 122v and a second bending unit 126v are formed. That is, the first external terminal unit 122, the connection lead unit 124, and the second external terminal unit 126 of each of the leads 120 may form one body. The first bending unit 122v may be formed between the first external terminal unit 122 and the connection lead unit 124, and the second bending unit 126v may be formed between the second external terminal unit 126 and the connection lead unit 124. Since the first external terminal unit 122 and the die paddle unit 110 are also formed from the lead frame, the first surface 103 and the second surface 104 of the first external terminal unit 122, and the first and second surfaces 112 and 114 of the die paddle unit 110 may be disposed on the same imaginary plane. That is, the first external terminal unit 122 and the die paddle unit 110 may be disposed on the same imaginary plane to have the same level.

A terminology “lead’ is used because the leads 120 each formed of the first external terminal unit 122, the connection lead unit 124, and the second external terminal unit 126 are formed from the lead frame. However, the semiconductor package 1000 according to an embodiment of the present invention may be a package of a quad flat no-leads (QFN) method because the semiconductor package 1000 does not have any lead protruding to the outside.

The bonding wire 200 may be formed to connect the semiconductor die 10 to the first external terminal unit 122. The bonding wire 200 may electrically connect the semiconductor die 10 to the outside through the first external terminal unit 122 by being connected to the first surface 102 of the first external terminal unit 122 from a surface of the semiconductor die 10, which is opposite to the surface that faces the die paddle unit 110. The bonding wire 200 may be formed as, for example, a gold wire. The bonding wire 200 may be connected to a pad unit (not shown) formed on the semiconductor die 10. Also, although not shown, the bonding wire 200 may be formed to connect a pad unit (not shown) for grounding to the die paddle unit 110.

The bonding wires 200 may connect the semiconductor die 10 to all of the first external terminal units 122 of the leads 120. However, optionally, the bonding wires 200 that connect the first external terminal units 122 of some of the leads 120 to the semiconductor die 10 may not be formed. When there are leads 120 that are not connected to the bonding wire 200, the leads 120 may function as conductive paths that electrically connect devices (semiconductor devices or passive devices) disposed on the lower surface 1004 of the semiconductor package 1000 to devices (semiconductor devices or passive devices) disposed on the upper surface 1002 of the semiconductor package 1000.

The sealing member 300 may be formed to completely surround the semiconductor die 10 and the bonding wire 200, and thus, protects the semiconductor die 10 and the bonding wire 200 from the outside. The sealing member 300 may be formed of, for example, an epoxy mold compound (EMC). The sealing member 300 may be formed to expose the second surface 114 of the die paddle unit 110. The sealing member 300 may be formed to expose the second surface 104 of the first external terminal unit 122 and the first surface 102 of the second external terminal unit 126.

In the semiconductor package 1000, the second surface 104 of the first external terminal unit 122, the first surface 102 of the second external terminal unit 126, and the second surface 114 of the die paddle unit 110 may only be exposed, and the other portions of the semiconductor package 1000 may be surrounded by the sealing member 300. However, a portion of a side surface of the first external terminal unit 122 may be exposed by the sealing member 300. Accordingly, as described above, the semiconductor package 1000 may be a package of a QFN method having a lead extruded to the outside.

As will be described, the semiconductor package 1000 may be used for forming a stacked semiconductor package, or the semiconductor die 10 of the semiconductor package 1000 may be electrically connected to the outside through the upper and lower surfaces 1002 and 1004 of the semiconductor package 1000 by optionally using the first external terminal unit 122 and the second external terminal unit 126 of the semiconductor package 1000.

A first height d1, which is a separation distance between the first external terminal unit 122 and the second external terminal unit 126, may have a value larger than a second height d2, which is the thickness of the semiconductor die 10. Although the upper surface 1002 of the semiconductor package 1000 is a plane that is formed by an upper surface of the sealing member 300 and the first surface 102 of the second external terminal unit 126, the semiconductor die 10 may not be exposed because the semiconductor die 10 is surrounded by the sealing member 300. Also, a third height d3, which is a height of the bonding wire 200 with respect to the die paddle unit 110, may be greater than the second height d2 and smaller than the first height d1.

The first external terminal unit 122 and the second external terminal unit 126 may be formed to partly overlap in a perpendicular direction with respect to the die paddle unit 110, that is, in a perpendicular direction with respect to the second surface 114 of the die paddle unit 110 or the lower surface 1004 of the semiconductor package 1000.

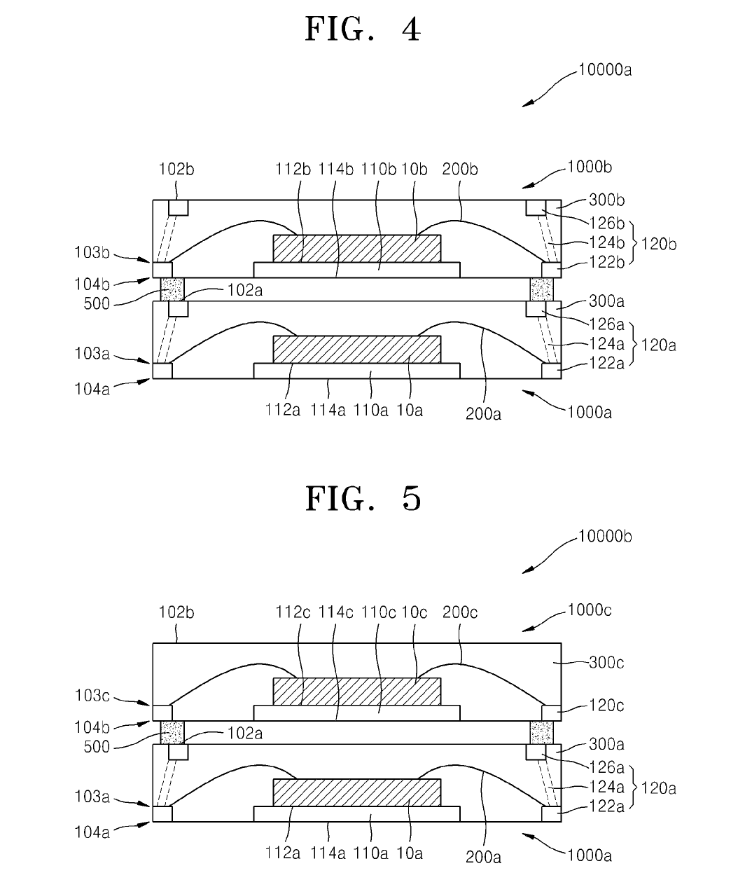

FIG. 4 is a cross-sectional view of a stacked semiconductor package 10000a according to an embodiment of the present invention.

Referring to FIG. 4, the stacked semiconductor package 10000a may include at least two semiconductor chips, that is, first and second semiconductor chips 1000a and 1000b. The first and second semiconductor chips 1000a and 1000b may be the same type as the semiconductor package 1000 shown in FIGS. 1 through 3 or a different kind of similar-sized semiconductor packages. Constituent elements of the first and second semiconductor chips 1000a and 1000b may be substantially the same as the constituent elements of the semiconductor package 1000 shown in FIGS. 1 through 3. The constituent elements of the first and second semiconductor chips 1000a and 1000b that are substantially the same as the constituent elements of the semiconductor package 1000 shown in FIGS. 1 through 3 may use reference numerals added respectively ‘a’ or ‘b’ to the reference numerals of the semiconductor package 1000. As described above, the first and second semiconductor chips 1000a and 1000b may have individual shapes of semiconductor packages respectively formed by using sealing members 300a and 300b. However, hereinafter, in the case of a semiconductor package that constitutes a stacked semiconductor package, for convenience of explanation, the semiconductor package may be referred to as a semiconductor chip.

The first and second semiconductor chips 1000a and 1000b may be electrically connected to each other through a bump terminal 500. The bump terminal 500 may be formed as a monolayer structure or a multi-layer structure that includes a metal selected from the group consisting of solder, Au, Cu, and Ni.

The bump terminal 500 may be formed on a second external terminal unit 126a of the first semiconductor chip 1000a. The second semiconductor chip 1000b may be stacked on the first semiconductor chip 1000a so the bump terminal 500 is connected to a first external terminal unit 122b.

A first external terminal unit 122a and a second external terminal unit 126a of the first semiconductor chip 1000a may be formed to partly overlap in a perpendicular direction with respect to a die paddle unit 110a, that is, in a perpendicular direction with respect to a second surface 114a of the die paddle unit 110a. If the first external terminal units 122a and 122b and the second external terminal units 126a and 126b of the first and second semiconductor chips 1000a and 1000b have the same structures and dispositions, at least the first external terminal unit 122b of the second semiconductor chip 1000b may correspond to partly overlap with the second external terminal unit 126a of the first semiconductor chip 1000a.

Accordingly, when only the bump terminal 500 is additionally formed, the highly difficult forming of a complicated wire bonding or a through silicon via (TSV) is unnecessary for forming the stacked semiconductor package 10000a.

Although not shown, after an additional bump terminal (not shown) is formed on the second external terminal unit 126b of the second semiconductor chip 1000b by using the same method, a third semiconductor chip (not shown) may be connected. In this way, a stacked semiconductor package having three or more semiconductor chips may be formed.

FIG. 5 is a cross-sectional view of a modified version of a stacked semiconductor package 10000b according to an embodiment of the present invention.

Referring to FIG. 5, the stacked semiconductor package 10000b may include at least two semiconductor chips, that is, a semiconductor chip 1000a and an upper semiconductor chip 1000c. The semiconductor chip 1000a may be the same type as the semiconductor package 1000 shown in FIGS. 1 through 3. The upper semiconductor chip 1000c is the uppermost semiconductor chip of the stacked semiconductor package 10000b and may not include elements corresponding to the connection lead unit 124 and the second external terminal unit 126 of the semiconductor package 1000. The upper semiconductor chip 1000c may include an external connection terminal 120c aligned with the second external terminal unit 126 of the semiconductor package 1000.

The stacked semiconductor package 10000b may be formed by attaching the upper semiconductor chip 1000c so that an external connection terminal 126c of the prepared upper semiconductor chip 1000c contacts the bump terminal 500 after forming the bump terminal 500 on a first surface 102a of the second external terminal unit 126a of the semiconductor chip 1000a.

The first external terminal unit 122a and the second external terminal unit 126a of the first semiconductor chip 1000a may be formed to partly overlap in a perpendicular direction with respect to the die paddle unit 110a, that is, in a perpendicular direction with respect to the second surface 114a of the die paddle unit 110a. However, in consideration of a size (area) of the upper semiconductor chip 1000c and the size or location of the external connection terminal unit 120c of the upper semiconductor chip 1000c, the first external terminal unit 122a and the second external terminal unit 126a may not overlap in a perpendicular direction with respect to the die paddle unit 110a, that is, in a perpendicular direction with respect to the second surface 114a of the die paddle unit 110a. Accordingly, when the second external terminal unit 126a of the semiconductor chip 1000a is formed to correspond to the external connection terminal unit 120c of the upper semiconductor chip 1000c that is to be stacked on an upper side of the semiconductor chip 1000a, a stacked semiconductor package may be formed by stacking different kinds of semiconductor chips.

Referring to FIGS. 4 and 5, when a stacked semiconductor package is formed by stacking more than three semiconductor chips, the uppermost semiconductor chip may not include constituent elements corresponding to the connection lead unit 124 and the second external terminal unit 126 shown in FIGS. 1 through 3.

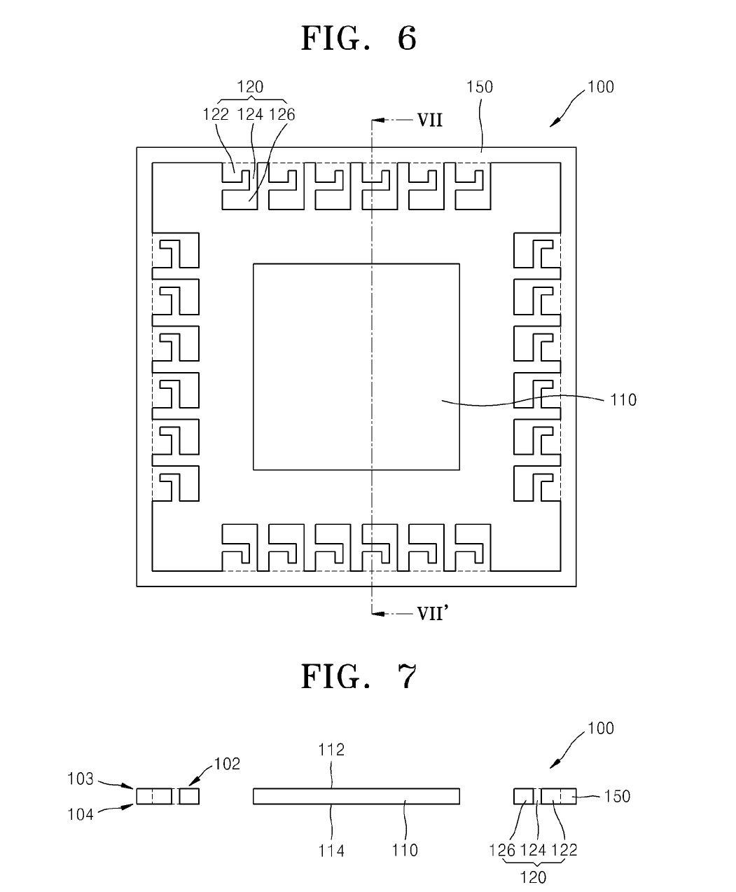

FIGS. 6 through 11 are plan views and cross-sectional views showing a method of fabricating a semiconductor package, according to an embodiment of the present invention.

FIGS. 6 and 7 are respectively a plan view and a cross-sectional view showing an operation of preparing a lead frame 100, according to an embodiment of the present invention. More specifically, FIG. 7 is a cross-sectional view taken along the line VII-VII′ of FIG. 6.

Referring to FIGS. 6 and 7, the lead frame 100 includes a first surface 102 and a second surface 104. The lead frame 100 may include a plurality of leads 120 connected to a die paddle unit 110 and a damber line 150. Although not shown, the lead frame 100 may further include a tie bar that connects the die paddle unit 110 to the damber line 150 to form the die paddle unit 110, the leads 120, and the damber line 150 as one body. Each of the leads 120 may include a first external terminal unit 122, a connection lead unit 124, and a second external terminal unit 126.

The first and second surfaces 102 and 104 of the lead frame 100 may be provided in the leads 120, that is, the first external terminal unit 122, the connection lead unit 124, and the second external terminal unit 126. Here, in order to describe with respect to the die paddle unit 110, first and second surfaces 112 and 114 of the lead frame 100 are referred to with respect to the die paddle unit 110 instead of the first and second surfaces 102 and 104 of the lead frame 100. In an operation of preparing the lead frame 100, the first and second surfaces 112 and 114 of the die paddle unit 110 denote surfaces that are flush with the first and second surfaces 102 and 104 of the lead frame 100, that is, on the same imaginary plane. However, hereinafter, other constituent elements, for example, a first or second surface 102 or 104 of the first or second external terminal unit 122 or 126 may or may not be the same surfaces as the first and second surfaces 112 and 114 of the die paddle unit 110. However, the first and second surfaces 102 and 104 of the first external terminal unit 122 or the second external terminal unit 126 denote portions of the first and second surfaces 102 and 104 of the lead frame 100, which are on the same plane as the first and second surfaces 112 and 114 of the die paddle unit 110.

In the cross-sectional view of FIG. 7, the connection lead unit 124 that is not located on the line VII-VII′ of FIG. 6 is indicated as dotted lines, and other constituents that are not located on the line VII-VII′ of FIG. 6 are omitted for convenience of explanation.

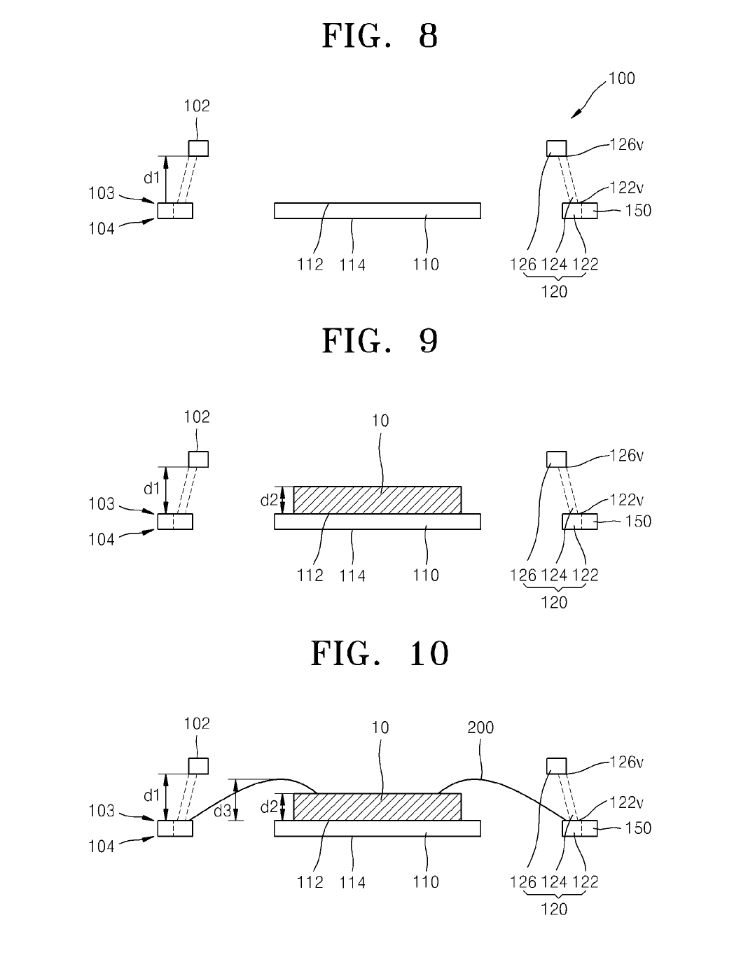

FIG. 8 is a cross-sectional view showing an operation of forming the lead frame 100, according to an embodiment of the present invention.

Referring to FIG. 8, an operation of bending a portion of the lead frame 100 is performed. The lead frame 100 is formed so that each of the leads 120 has a first bending unit 122v and a second bending unit 126v, and thus, the first external terminal unit 122, the connection lead unit 124, and the second external terminal unit 126 of each of the leads 120 may be differentiated. The connection lead unit 124 may have the first bending unit 122v between the connection lead unit 124 and the first external terminal unit 122, and the connection lead unit 124 may protrude higher than the first surface 112 of the die paddle unit 110. Also, the second external terminal unit 126 may have the second bending unit 126v between the second external terminal unit 126 and the connection lead unit 124 such that the second external terminal unit 126 protrudes higher than the first surface 112 of the die paddle unit 110. The second bending unit 126v may be formed so that the first surface 102 of the second external terminal unit 126 is substantially parallel to the second surface 104 of the first external terminal unit 122. The first external terminal unit 122 and the die paddle unit 110 may be disposed on the same imaginary plane.

The first bending unit 122v and the second bending unit 126v may be formed to have a first height d1, which is a distance between the first external terminal unit 122 and the second external terminal unit 126.

The first external terminal unit 122 and the second external terminal unit 126 may be formed to partly overlap in a perpendicular direction with respect to the die paddle unit 110, that is, in a perpendicular direction with respect to the second surface 114 of the die paddle unit 110 or the lower surface 1004 of the semiconductor package 1000. Also, the first external terminal unit 122 and the second external terminal unit 126 may be formed not to overlap in a perpendicular direction with respect to the die paddle unit 110, that is, in a perpendicular direction with respect to the second surface 114 of the die paddle unit 110.

FIG. 9 is a cross-sectional view showing an operation of attaching the semiconductor die 10, according to an embodiment of the present invention.

Referring to FIG. 9, the semiconductor die 10 is attached onto the die paddle unit 110. The semiconductor die 10 may be attached onto the first surface 112 of the die paddle unit 110. In order to attach the semiconductor die 10 onto the first surface 112 of the die paddle unit 110, a film on which an epoxy resin or an adhesive member is coated or a film having adhesiveness may be disposed between the semiconductor die 10 and the first surface 112 of the die paddle unit 110. A surface of the semiconductor die 10 opposite to the surface that faces the die paddle unit 110 may be an active surface of the semiconductor die 10.

A second height d2, which is the height of the semiconductor die 10 may have a value smaller than a first height d1, which is a distance between the first external terminal unit 122 and the second external terminal unit 126. That is, the second height d2 may be determined so that the second external terminal unit 126 is disposed higher than the semiconductor die 10 with respect to the die paddle unit 110.

FIG. 10 is a cross-sectional view showing an operation of forming the bonding wire 200, according to an embodiment of the present invention.

Referring to FIG. 10, the bonding wire 200 may be formed to connect the semiconductor die 10 to the first external terminal unit 122 of each of the leads 120. The bonding wire 200 is connected to the first surface 102 of the first external terminal unit 122 from an opposite surface to a surface of the semiconductor die 10 that faces the die paddle unit 110 so that the semiconductor die 10 is electrically connected to the outside through the first external terminal unit 122. The bonding wire 200 may be formed as, for example, a gold wire. The bonding wire 200 may be connected to a pad unit (not shown) formed on the semiconductor die 10. Although not shown, the bonding wire 200 may be formed to connect a grounding pad (not shown) of the semiconductor die 10 to the die paddle unit 110.

The bonding wire 200 may connect the semiconductor die 10 to all of the first external terminal units 122 of the leads 120. However, optionally, the bonding wires 200 that connect the first external terminal units 122 of some of the leads 120 to the semiconductor die 10 may not be formed. When there are leads 120 that are not connected to the bonding wire 200, the leads 120 may function as conductive paths that electrically connect devices (semiconductor devices or passive devices) disposed on the lower surface 1004 of the semiconductor package 1000 to devices (semiconductor devices or passive devices) disposed on the upper surface 1002 of the semiconductor package 1000.

A third height d3, which is a height of the bonding wire 200 with respect to the die paddle unit 110, may be greater than the second height d2 and smaller than the first height d1.

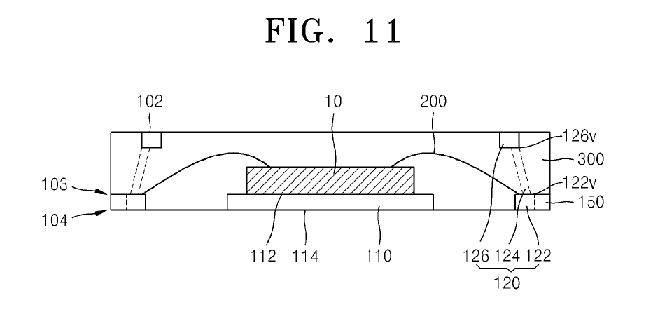

FIG. 11 is a cross-sectional view showing an operation of forming the sealing member 300, according to an embodiment of the present invention.

Referring to FIG. 11, the sealing member 300 may be formed to completely surround the semiconductor die 10 and the bonding wire 200 to protect the semiconductor die 10 and the bonding wire 200 from the outside. The sealing member 300 may be formed of, for example, an EMC. The sealing member 300 may be formed to expose the second surface 114 of the die paddle unit 110. The sealing member 300 may be formed to expose the second surface 104 of the first external terminal unit 122 and the first surface 102 of the second external terminal unit 126.

Referring to FIG. 3, a singulation operation for removing a portion of the sealing member 300 and the damber line 150 is performed to form the individual semiconductor package 1000. Through the singulation operation, the leads 120 may be separated from each other.

The semiconductor package and the stacked semiconductor package using the semiconductor package according to the present invention may be formed by using the method of fabricating the semiconductor package according to the present invention without using a complicated wire bonding process or a highly difficult process, such as a TSV. Also, in the stacked semiconductor package formed by stacking the same type of semiconductor packages as well as in the stacked semiconductor package formed by stacking different types of semiconductor packages, the method of fabricating the semiconductor package according to the present invention may be readily applied through modifying the design of lead frames or lead frame forming process.

Even though a stacked semiconductor package is not formed, terminals for electrical connection to external devices are formed on both sides of the semiconductor package. Therefore, the semiconductor package according to the present invention may be applied to complicated electronic devices.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
a die paddle unit having a first surface and a second surface opposite to the first surface;
a semiconductor die attached to the first surface of the die paddle unit;
a plurality of leads each comprising a first external terminal unit, a second external terminal unit, and a connection lead unit that connects the first external terminal unit to the second external terminal unit;
a bonding wire that connects the semiconductor die to the first external terminal unit; and
a sealing member formed to expose the first external terminal unit and the second external terminal unit and to surround the semiconductor die and the bonding wire.

2. The semiconductor package of claim 1, wherein the first external terminal unit and the die paddle unit are disposed on the same imaginary plane and the sealing member is formed to expose the second surface of the die paddle unit.

3. The semiconductor package of claim 1, wherein the first external terminal unit and the second external terminal unit of each of the leads partly overlap in a direction perpendicular to the second surface.

4. The semiconductor package of claim 1, wherein a distance between the first external terminal unit and the second external terminal unit has a value greater than the thickness of the semiconductor die.

5. A stacked semiconductor package comprising:
a first semiconductor chip and a second semiconductor chip each comprising:
a die paddle unit having a first surface and a second surface opposite to the first surface;
a semiconductor die attached to the first surface of the die paddle unit;
a plurality of leads each comprising a first external terminal unit, a second external terminal unit, and a connection lead unit that connects the first external terminal unit to the second external terminal unit;
a bonding wire that connects the semiconductor die to the first external terminal unit; and
a sealing member formed to expose the first external terminal unit and the second external terminal unit and to surround the semiconductor die and the bonding wire,
wherein the first semiconductor chip is stacked on the second semiconductor chip, and further comprises a bump terminal that is disposed between the second external terminal unit of the first semiconductor chip and the first external terminal unit of the second semiconductor chip to electrically connect the first semiconductor chip to the second semiconductor chip.

6. A method of fabricating a stacked semiconductor package, the method comprising:
preparing a lead frame having a first surface and a second surface opposite to the first surface, a plurality of leads each comprising a first external terminal unit, a second external terminal unit, and a connection lead unit that connects the first external terminal unit to the second external terminal unit, and a die paddle unit;
forming the lead frame to form a first bending unit and a second bending unit respectively between the first external terminal unit and the connection lead unit and between the second external terminal unit and the connection lead unit;
attaching the semiconductor die onto the first surface of the die paddle unit;
forming a bonding wire that connects the semiconductor die to the first surface of the first external terminal unit; and
forming a sealing member that surrounds some portions of the leads to expose the second surface of the first external terminal unit and the first surface of the second external terminal unit, the semiconductor die, and the bonding wire.

7. The method of claim 6, wherein the forming of the lead frame comprises disposing the first external terminal unit and the die paddle unit on the same imaginary plane.

8. The method of claim 6, wherein the forming of the lead frame comprises partly overlapping the first external terminal unit and the second external terminal unit of each of the leads in a direction perpendicular to the first surface.

9. The method of claim 6, wherein the forming of the lead frame comprises forming a distance between the first and second external terminal units of each of the leads to be greater than the thickness of the semiconductor die.

10. The method of claim 6, further comprising:
preparing an upper semiconductor chip having an external connection terminal;
forming a conductive bump on the first surface of the second external terminal unit; and
attaching the upper semiconductor chip so that the conductive bump contacts the external connection terminal.
